(19) United States
(12) Patent Application Publication
(10) Pub. No.: US 2016/0188405 A1
(43) Pub. Date: Jun. 30, 2016

(54) ADAPTIVE ECC TECHNIQUES FOR FLASH MEMORY BASED DATA STORAGE

(71) Applicant: Seagate Technology LLC, Cupertino, CA (US)

(72) Inventors: Yan Li, San Jose, CA (US); Hao Zhong, Milpitas, CA (US); Radoslav Danilak, Cupertino, CA (US); Earl T Cohen, Oakland, CA (US)

(73) Assignee: SEAGATE TECHNOLOGY LLC, Cupertino, CA (US)

(21) Appl. No.: 14/945,276

(22) Filed: Nov. 18, 2015

Related U.S. Application Data
(63) Continuation of application No. 13/879,383, filed on Oct. 15, 2013.
(60) Provisional application No. 61/407,178, filed on Oct. 27, 2010.

(51) Int. Cl. G06F 11/10; G11C 29/52; H03M 13/29; G11C 11/56

(52) U.S. Cl. CPC G06F 11/1068; G11C 11/5628; G11C 29/52; H03M 13/2906

(57) ABSTRACT

Adaptive ECC techniques for use with flash memory enable improvements in flash memory lifetime, reliability, performance, and/or storage capacity. The techniques include a set of ECC schemes with various code rates and/or various code lengths (providing different error correcting capabilities), and error statistic collecting/tracking (such as via a dedicated hardware logic block). The techniques further include encoding/decoding in accordance with one or more of the ECC schemes, and dynamically switching encoding/decoding amongst one or more of the ECC schemes based at least in part on information from the error statistic collecting/tracking (such as via a hardware logic adaptive codec receiving inputs from the dedicated error statistic collecting/tracking hardware logic block). The techniques further include selectively operating a portion (e.g., page, block) of the flash memory in various operating modes (e.g. as an MLC page or an SLC page) over time.

### CROSS REFERENCE TO RELATED APPLICATIONS

Priority benefit claims for this application are made in the accompanying Application Data Sheet, Request, or Transmittal (as appropriate, if any). To the extent permitted by the type of the instant application, this application incorporates by reference for all purposes the following applications, all commonly owned with the instant application at the time the invention was made:
U.S. Provisional Application (Docket No. SF-10-03 and Ser. No. 61/407.178), filed 27 Oct. 2010, first named inventor Yan Li, and entitled Adaptive ECC Techniques for Flash Memory Based Data Storage.

### BACKGROUND

1. Field

Advancements in flash memory storage technology are needed to provide improvements in performance, efficiency, and utility of use.

2. Related Art

Unless expressly identified as being publicly or well known, mention herein of techniques and concepts, including for context, definitions, or comparison purposes, should not be construed as an admission that such techniques and concepts are previously publicly known or otherwise part of the prior art. All references cited herein (if any), including patents, patent applications, and publications, are hereby incorporated by reference in their entireties, whether specifically incorporated or not, for all purposes.

### SYNOPSIS

The invention may be implemented in numerous ways, including as a process, an article of manufacture, an apparatus, a system, a composition of matter, and a computer readable medium such as a computer readable storage medium (e.g. media in an optical and/or magnetic mass storage device such as a disk, or an integrated circuit having non-volatile storage such as flash storage) or a computer network wherein program instructions are sent over optical or electronic communication links. In this specification, these implementations, or any other form that the invention may take, may be referred to as techniques. The Detailed Description provides an exposition of one or more embodiments of the invention that enable improvements in performance, efficiency, and utility of use in the field identified above. The Detailed Description includes an Introduction to facilitate the more rapid understanding of the remainder of the Detailed Description. The Introduction includes Example Embodiments of one or more of systems, methods, articles of manufacture, and computer readable media in accordance with the concepts described herein. As is discussed in more detail in the Conclusions, the invention encompasses all possible modifications and variations within the scope of the issued claims.

### BRIEF DESCRIPTION OF DRAWINGS

FIG. 1 illustrates selected details of an embodiment of a system using adaptive ECG techniques for flash memory based data storage.

FIG. 2A illustrates selected details of an embodiment of an SSD including an SSD controller using adaptive ECC techniques for flash memory based data storage.

FIG. 2B illustrates selected details of an embodiment of a system including the SSD of FIG. 2A.

FIG. 2C illustrates selected details of another embodiment of a system including the SSD of FIG. 2A.

List of Reference Symbols in Drawings

| Ref. Symbol | Element Name |
|---|---|
| 100 | System |
| 110 | Write-Storage-Data Path |
| 120 | Universal Encoder |
| 130 | Control/Interface |
| 140 | Flash Unit |
| 150 | Read-Storage-Data Path |
| 160 | Universal Decoder |
| 170 | Code Library |
| 180 | Error Statistics Collecting/Tracking |
| 200 | SSD Controller |
| 201 | SSD |
| 202 | Host |
| 203 | Intermediate Controller |
| 204 | Intermediate Interfaces |
| 210 | External Interfaces |
| 211 | Host Interfaces |
| 213 | Tag Tracking |
| 221 | Data Processing |
| 223 | Engines |
| 231 | Buffer |
| 233 | DMA |
| 237 | Memory |
| 241 | Map |
| 243 | Table |
| 251 | Recycler |
| 261 | ECC |
| 271 | CPU |
| 273 | Command Management |
| 275 | Buffer Management |
| 277 | Translation Management |
| 279 | Coherency Management |
| 281 | CPU Core |
| 282 | Device Management |
| 290 | Device Interfaces |
| 291 | Device Interface Logic |
| 292 | Flash Device |
| 293 | Scheduling |
| 294 | Flash Die |
| 299 | Non-Volatile Memory |

### DETAILED DESCRIPTION

A detailed description of one or more embodiments of the invention is provided below along with accompanying figures illustrating selected details of the invention. The invention is described in connection with the embodiments. The embodiments herein are understood to be merely exemplary, the invention is expressly not limited to or by any or all of the embodiments herein, and the invention encompasses numerous alternatives, modifications, and equivalents. To avoid monotony in the exposition, a variety of word labels (including but not limited to: first, last, certain, various, further, other, particular, select, some, and notable) may be applied to separate sets of embodiments; as used herein such labels are expressly not meant to convey quality, or any form of preference or prejudice, but merely to conveniently distinguish among the separate sets. The order of some operations of disclosed processes is alterable within the scope of the invention. Wherever multiple embodiments serve to describe variations in process, method, and/or program instruction features, other embodiments are contemplated that in accordance with a predetermined or a dynamically determined criterion perform static and/or dynamic selection of one of a plurality of modes of operation corresponding respectively to a plurality of the multiple embodiments. Numerous specific details are set forth in the following description to provide a thorough understanding of the invention. The details are provided for the purpose of example and the invention may be practiced according to the claims without some or all of the details. For the purpose of clarity, technical material that is known in the technical fields related to the invention has not been described in detail so that the invention is not unnecessarily obscured.

### Introduction

This introduction is included only to facilitate the more rapid understanding of the Detailed Description; the invention is not limited to the concepts presented in the introduction (including explicit examples, if any), as the paragraphs of any introduction are necessarily an abridged view of the entire subject and are not meant to be an exhaustive or restrictive description. For example, the introduction that follows provides overview information limited by space and organization to only certain embodiments. There are many other embodiments, including those to which claims will ultimately be drawn, discussed throughout the balance of the specification.

### Acronyms

Elsewhere herein various shorthand abbreviations, or acronyms, refer to certain elements. The descriptions of at least some of the acronyms follow.

| Acronym | Description |
|---|---|
| BCH | Bose Chaudhuri Hocquenghem |
| BER | Bit Error Rate |
| CD | Compact Disk |
| CF | Compact Flash |
| CMOS | Complementary Metal Oxide Semiconductor |
| CPU | Central Processing Unit |
| CRC | Cyclic Redundancy Check |
| DDR | Double-Data-Rate |
| DMA | Direct Memory Access |
| DVD | Digital Versatile/Video Disk |
| ECC | Error-Correcting Code |
| HDD | Hard Disk Drive |
| IC | Integrated Circuit |
| LBA | Logical Block Address |
| LDPC | Low-Density Parity-Check |
| MLC | Multi-Level Cell |
| MMC | MultiMediaCard |
| NCQ | Native Command Queuing |
| ONFI | Open NAND Flash Interface |
| PC | Personal Computer |
| PCIe | Peripheral Component Interconnect express (PCI express) |
| PDA | Personal Digital Assistant |
| PE | Program/Erase |
| PRBS | Pseudo-Random Bit Sequence |
| RAID | Redundant Array of Inexpensive/Independent Disks |
| RS | Reed-Solomon |
| SAS | Serial Attached Small Computer System Interface (Serial |
| | SCSI) |
| SATA | Serial Advanced Technology Attachment (Serial ATA) |
| SD | Secure Digital |
| SLC | Single-Level Cell |
| SMART | Self-Monitoring Analysis and Reporting Technology |
| SSD | Solid State Disk/Drive |
| USB | Universal Serial Bus |

NAND flash memory uses an array of floating gate transistors to store information. In SLC technology, each bit cell (e.g. floating gate transistor) is enabled to store one bit of information. In MLC technology, each bit cell is enabled to store multiple bits of information. As manufacturing technology (e.g. CMOS technology) scales down, each floating gate stores fewer electrons. Further, as storage capacity and density increase, each bit cell stores more bits. Therefore, values stored in the bit cells are represented by smaller voltage ranges. Uncertainties in sensing and/or changes in amount of stored electrons over time increase a probability for data to be stored or read incorrectly. Use of one or more ECC techniques enables correct retrieval of otherwise corrupted data.

Some SSDs use flash memory to provide non-volatile storage (e.g. information is retained without application of power). Some SSDs are compatible with form-factors, electrical interfaces, and/or protocols used by magnetic and/or optical non-volatile storage, such as HDDs, CD drives, and DVD drives. In various embodiments, SSDs use various combinations of zero or more RS codes, zero or more BCH codes, zero or more Viterbi or other trellis codes, and zero or more LDPC codes.

An example of raw BER is a BER of data read from a flash memory without benefit of ECC. Several factors contribute to the raw BER (such as write errors, retention errors, and read-disturb errors), and the raw BER is changeable over time. Storing data in a flash memory is a two part process: first a block of the flash memory is erased, and then the block is written. The two part process is an example of a PE cycle. In various usage scenarios and/or embodiments, all or one or more portions of errors of a flash memory are functions of how many PE cycles a particular block in the flash memory has undergone. In some usage scenarios and/or embodiments, as a particular block is PE cycled (e.g. erased and then written), raw BER of the particular block increases.

In some approaches, fixed ECC is used throughout a lifetime of a flash memory. For example, a single ECC scheme is used from the first time a flash memory is operated throughout the last time the flash memory is operated. The single ECC scheme is designed to have sufficient error correcting capability to correct for a worst possible raw BER throughout the lifecycle of the flash memory (e.g. enabled to correct during late-lifetime of the flash memory). The error correcting capability is more than sufficient to correct errors arising from relatively low raw BER during early- and mid-lifetime of the flash memory, thus reducing effective storage capacity (as more storage capacity is devoted to ECC than needed to correct errors).

In various embodiments and/or usage scenarios, adaptive ECC techniques for use with flash memory enable improvements in flash memory lifetime, reliability, performance, and/or storage capacity. The techniques include a set of ECC schemes with various code types, code rates, and/or various code lengths (providing different error correcting capabilities), and error statistic collecting/tracking (such as via a dedicated hardware logic block). The techniques further include encoding/decoding in accordance with one or more of the ECC schemes, and dynamically switching encoding/decoding of all or any portions of the flash memory amongst a respective one or more of the ECC schemes based at least in part on information from the error statistic collecting/tracking (such as via a hardware logic adaptive codec receiving inputs from the dedicated error statistic collecting/tracking hardware logic block). The techniques further include selectively operating a portion (e.g. a page or a block) of the flash memory in various operating modes (e.g. as an MLC page or an SLC page) over time. For example, a shorter length code is used during an early portion of a flash memory lifetime, and a longer length code is used during a later portion of the lifetime. For another example, during an operating period of a page of a flash memory, the page is operated as an MLC page, and then during a subsequent operating period, the page is operated as an SLC page. The lifetime or the operating period are measureable according to, e.g., time that power is applied, a number of program/erase cycles, a number of read cycles, a measured and/or estimated BER, a program time, an erase time, a read time, a temperature, and/or a threshold voltage of a storage cell of the flash memory.

### Example Embodiments

In concluding the introduction to the detailed description, what follows is a collection of example embodiments, including at least some explicitly enumerated as “ECs” (Example Combinations), providing additional description of a variety of embodiment types in accordance with the concepts described herein; these examples are not meant to be mutually exclusive, exhaustive, or restrictive; and the invention is not limited to these example embodiments but rather encompasses all possible modifications and variations within the scope of the issued claims.

EC1) A system, comprising:
an error statistics collecting and tracking hardware logic block enabled to determine a raw Bit Error Rate (BER) of accesses to a portion of a flash memory; and
an adaptive encoder hardware block enabled to encode according to a selected one of a plurality of error correcting codes, and further enabled to dynamically determine the selected error correcting code based at least in part on the raw BER.

EC2) The system of EC1, wherein encoding according to one of the error correcting codes results in a number of error correcting bits to store in the portion that is less than encoding according to another one of the error correcting codes.

EC3) The system of EC1, wherein encoding according to one of the error correcting codes results in a number of error correcting bits to store in the portion that is more than encoding according to another one of the error correcting codes.

EC4) The system of EC1, wherein relatively more data information and relatively less error correcting information is output by the adaptive encoder when the selected error correcting code is a first one of the error correcting codes compared to a second one of the error correcting codes.

EC5) The system of EC4 wherein the amount of data information when the selected error correcting code is the first error correcting code is larger than the amount of data information when the selected error correcting code is the second error correcting code.

EC6) The system of EC4 wherein the amount of data information when the selected error correcting code is the second error correcting code is a power of two.

EC7) The system of EC4 wherein the amount of data information when the selected error correcting code is the second error correcting code is a power of two, and wherein the amount of data information when the selected error correcting code is the first error correcting code is larger than the amount of data information when the selected error correcting code is the second error correcting code.

EC8) The system of EC1, further comprising an adaptive decoder enabled to decode according to any of the error correcting codes.

EC9) The system of EC1, wherein the error correcting codes comprise only Reed-Solomon (RS) codes.

EC10) The system of EC1, wherein the error correcting codes comprise only Bose Chaudhuri Hocquenghem (BCH) codes.

EC11) The system of EC1, wherein the error correcting codes comprise only Low-Density Parity-Check (LDPC) codes.

EC12) The system of EC1, wherein the error correcting codes comprise at least two types of error correcting codes, the types of error correcting codes comprising Reed-Solomon (RS) type codes, Bose Chaudhuri Hocquenghem (BCH) type codes, and Low-Density Parity-Check (LDPC) type codes.

EC13) The system of EC1, wherein at least two of the error correcting codes are of different code rates.

EC14) The system of EC1, wherein at least two of the error correcting codes are of different code lengths.

EC15) The system of EC1, wherein the portion is one or more blocks of the flash memory, each of the blocks being separately erasable.

EC16) The system of EC1, wherein the portion is one or more pages of the flash memory, each of the pages being separately writable.

EC17) The system of EC1, wherein the error statistics collecting and tracking hardware logic block is further enabled to determine respective raw BERs of accesses to respective portions of the flash memory.

EC18) The system of EC1, wherein the flash memory comprises one or more flash memory die.

EC19) The system of EC1, wherein the raw BER is an estimated raw BER.

EC20) The system of EC19, wherein the estimated raw BER is determined at least in part by counting how many program/erase cycles are performed on the portion.

EC21) The system of EC19, wherein the estimated raw BER is determined at least in part by counting how many read cycles are performed on the portion.

EC22) The system of EC19, wherein the estimated raw BER is determined at least in part by determining a threshold voltage associated with at least one cell of the portion.

EC23) The system of EC19, wherein the estimated raw BER is determined based at least in part on one or more pre-determined thresholds.

EC24) The system of EC19, wherein the estimated raw BER is determined based at least in part on one or more statistical models.

EC25) The system of EC1, wherein the raw BER is a measured raw BER.

EC26) The system of EC25, wherein the measured raw BER is determined periodically.

EC27) The system of EC25, wherein the measured raw BER is determined at least in part by writing a predetermined pattern to the portion and subsequently reading the portion.

EC28) The system of EC25, wherein the measured raw BER is determined at least in part by observing a BER associated with at least some reads of the portion.

EC29) The system of EC25, wherein the measured raw BER is determined at least in part by comparing raw read data from the flash memory with an error-corrected version of the raw read data.

EC30) The system of EC1, wherein the error statistics collecting and tracking hardware logic block is a distinct hardware logic block.

EC31) The system of EC1, wherein the error statistics collecting and tracking hardware logic block is a dedicated hardware logic block.

EC32) The system of EC1, wherein the error statistics collecting and tracking hardware logic block is a distributed hardware logic block.

EC33) The system of EC1, wherein the error statistics collecting and tracking hardware logic block is at least partially implemented in an adaptive decoder hardware logic block enabled to decode according to any of the error correcting codes.

EC34) The system of EC1, wherein the error statistics collecting and tracking hardware logic block is at least partially implemented in an adaptive decoder hardware logic block enabled to compare raw read data from the flash memory with an error-corrected version of the raw read data to at least in part determine the raw BER.

EC35) The system of EC1, wherein the error statistics collecting and tracking hardware logic block is at least partially implemented in a flash memory interface hardware logic block compatible with the flash memory and enabled to count how many program/erase cycles are performed on the portion, and the adaptive encoder is further enabled to dynamically determine the selected error correcting code based at least in part on the count.

EC36) The system of EC1, wherein the error statistics collecting and tracking hardware logic block is at least partially implemented in a flash memory interface hardware logic block compatible with the flash memory and enabled to count how many read cycles are performed on the portion, and the adaptive encoder is further enabled to dynamically determine the selected error correcting code based at least in part on the count.

EC37) The system of EC1, wherein the error statistics collecting and tracking hardware logic block is at least partially implemented in a flash memory interface hardware logic block compatible with the flash memory and enabled to determine a threshold voltage associated with at least one cell of the portion, and the adaptive encoder is further enabled to dynamically determine the selected error correcting code based at least in part on the threshold voltage.

EC38) The system of EC1, wherein the portion comprises a plurality of sub-portions, and the adaptive encoder is further enabled to encode such that error correcting information is storable to one or more of the sub-portions and data information is storable to only one of the sub-portions.

EG39) The system of EC1, wherein the hardware blocks are comprised in a Solid-State Disk (SSD) controller.

EC40) The system of EC1, wherein the hardware blocks are comprised in a Solid-State Disk (SSD).

EC41) The system of EC1, wherein the hardware blocks are comprised in a non-volatile storage component controller.

EC42) The system of EC1, wherein the hardware blocks are comprised in a non-volatile storage component.

EC43) The system of EC42, wherein the non-volatile storage component comprises one or more of a Universal Serial Bus (USB) storage component, a Compact Flash (CF) storage component, a MultiMediaCard (MMC) storage component, a Secure Digital (SD) storage component, a Memory Stick storage component, and an xD storage component.

EC44) A system, comprising:
an error statistics collecting and tracking hardware logic block enabled to determine a raw Bit Error Rate (BER) of accesses to a portion of a flash memory; and
an adaptive codec comprising an adaptive encoder and an adaptive decoder, the adaptive encoder enabled to encode according to a first selected one of a plurality of error correcting codes, the adaptive decoder enabled to decode according to a second selected one of the error correcting codes, and the adaptive codec further comprising a control hardware logic block enabled to determine the first selected one of the error correcting codes based at least in part on information received from the error statistics collecting and tracking hardware logic block.

EC45) The system of EC44, wherein the adaptive codec further comprises a code library enabled to describe each of the error correcting codes.

EC46) The system of EC44, wherein the adaptive encoder is a universal encoder enabled to encode according to any of the error correcting codes.

EC47) The system of EC44, wherein the adaptive decoder is a universal decoder enabled to decode according to any of the error correcting codes.

EC48) A system, comprising:
a code rate selection block enabled to determine a respective code rate associated with each of a plurality of portions of a flash memory;
an encoder operable according to the respective determined code rates;
a decoder operable according to the respective determined code rates; and
wherein a particular one of the portions of the flash memory is written with data encoded by the encoder according to a particular one of the respective determined code rates, and is subsequently read from the particular portion and decoded by the decoder.

EC49) The system of EC48, wherein the code rate selection block is comprised of hardware logic circuitry.

EG50) The system of EC48, wherein the code rate selection block is enabled to determine the respective code rate based at least in part on one or more parameters per one or more of the portions, or one or more histories of one or more of the parameters, the parameters comprising
a number of errors corrected,
a number of errors detected,
a number of program/erase cycles,
a number of read cycles,
a program time,
an erase time,
a read time,
a temperature, and
a threshold voltage.

### System and Operation

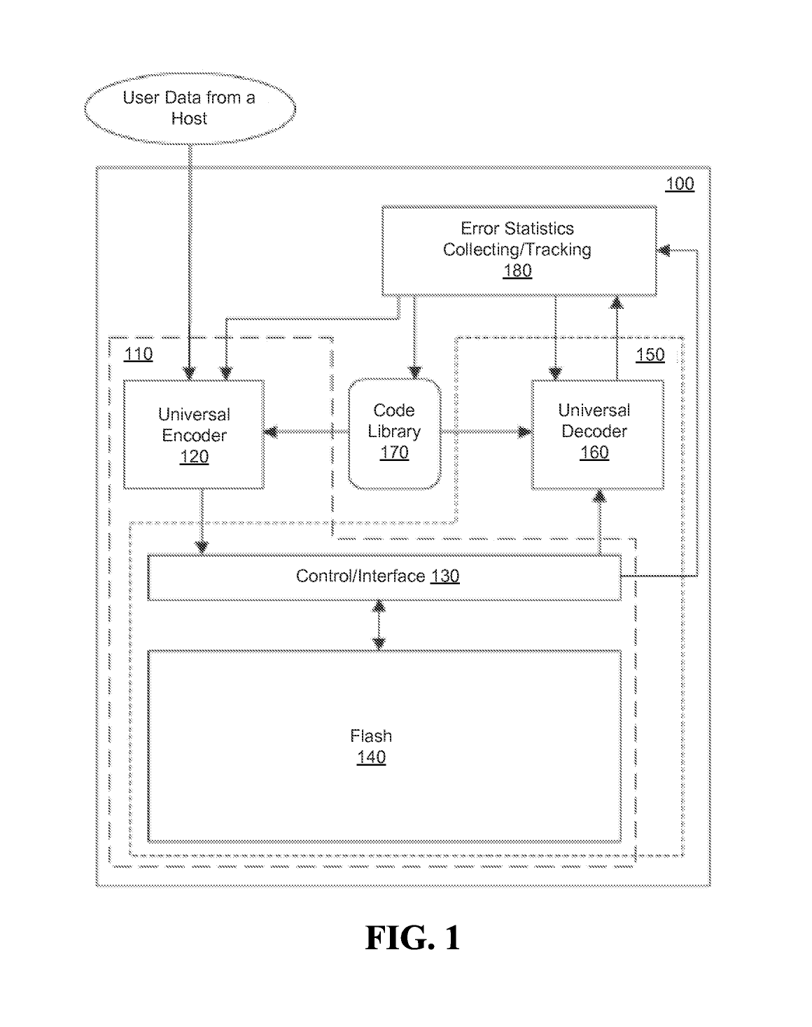

FIG. 1 illustrates selected details of an embodiment of a system 100 using adaptive ECC techniques for flash memory based data storage. A write-storage-data path 110 includes various hardware blocks: a Universal Encoder 120 coupled to a Control/Interface 130 that is in turn coupled to a Flash unit 140 (comprising, e.g. one or more flash memory die). A read-storage-data path 150 includes various hardware blocks: the Flash unit and the Control/Interface coupled to a Universal Decoder 160. A Code Library 170 hardware block is coupled to the Universal Encoder and the Universal Decoder hardware blocks. An Error Statistics Collecting/Tracking 180 hardware block is coupled to the Universal Encoder, the Code Library, the Universal Decoder, and the Control/Interface hardware blocks.

In operation, “User Data from a Host” to write as storage data is received by the Universal Encoder and encoded according to an error correcting code. The error correcting code is described by information from the Code Library, and is selected based in part on information such as provided by the Error Statistics Collecting/Tracking block. The Universal Encoder then provides data information and error correcting information to the Control/Interface that writes the information to the Flash unit.

Reading storage data begins by the Control/Interface reading raw information from one or more portions (e.g. pages or blocks) of the Flash unit, providing the raw information to the Universal Decoder. The Universal Decoder then decodes the raw information (including error corrections) into data information according to an error correcting code using error correcting information included in the raw information. The error correcting code is described by information from the Code Library, and is selected based in part on information such as provided by the Error Statistics Collecting/Tracking block and/or one or more portions of the raw information. The data information is then passed to the Host One or more alternate orderings of processing are performed in various alternate embodiments. For example, in some embodiments, reading storage data begins by reading the Code Library, followed by the Control/Interface reading raw information.

The error correcting code used for encoding (and decoding) is selected from a set of error correcting codes. In various embodiments, the set includes only RS codes, only BCH codes, only trellis codes, or only LDPC codes. In various embodiments, the set includes more than one type of code, such as various combinations of RS, BCH, trellis, and/or LDPC code types, and each of the code types includes one or more specific codes of the respective type. In various embodiments, the set includes codes of varying rates and/or lengths. In further embodiments, codes of one code type (such as a BCH code type) are used for higher-rate codes, and codes of another code type (such as an LDPC code type) are used for lower-rate codes.

The Error Statistics Collecting/Tracking hardware block is implemented as an independent functional hardware block or alternatively as a functional block distributed in one or more hardware blocks. For example, the Error Statistics Collecting/Tracking hardware block is implemented in part in the Universal Decoder hardware block, and is enabled to calculate a measured raw BER by comparing raw information read from the Flash unit with error-corrected data information produced by decoding the raw information. For another example, the Error Statistics Collecting/Tracking hardware block is implemented in part in the Control/Interface hardware block, and is enabled to calculate an estimated raw BER by counting a number of PE cycles and/or read cycles (e.g. per storage unit such as a page or a block of flash storage) and using the number as a parameter to a pre-determined statistical model that in turn provides an estimated raw BER. For yet another example, the Error Statistics Collecting/Tracking hardware block is implemented in part in the Control/Interface hardware block and is enabled to calculate an estimated raw BER by obtaining a threshold voltage (or a proxy thereof) for one or more cells read from a portion of flash storage (such as a page or a block of the flash storage) and using the voltage as a parameter to a pre-determined statistical model that in turn provides an estimated raw BER. For still yet another example, the Error Statistics Collecting/Tracking hardware block is enabled to provide one or more predetermined patterns to be written to flash storage (such as via bypassing the Universal Encoder) and is enabled to verify the number of raw bit errors returned from the flash storage (such as via bypassing the Universal Decoder) to determine a measured raw BER. The predetermined patterns include an all-zero pattern, an all-one pattern, or one or more PRBS patterns. As yet another example, the Error Statistics Collecting/Tracking hardware block is enabled to periodically determine (such as once every 100 PE cycles) a current raw (measured) BER of one or more portions of flash storage, e.g. via providing and verifying one or more of the predetermined patterns. As further examples, any one or more of the aforementioned examples are implemented in various combinations.

In various embodiments, one or more functions performed by the aforementioned Error Statistics Collecting/Tracking hardware block are implemented wholly or partially via one or more software techniques. For example, a programmable hardware timer provides an interrupt to a processor. In response, the processor executes a software interrupt handler routine that directs a portion of the Universal Decoder hardware block to provide one or more measured raw BER values to the processor. The processor accumulates the values as a moving average. The moving average is used at least in part to determine a selected error correcting code, such as via an input to a software function enabled to select an error correcting code, or alternatively as an input to a hardware unit enabled to select an error correcting code. For another example, a processor executes one or more software routines to count PE and/or read cycles per storage unit. The counting is via the routines reading a previous counter value from memory addressable by the processor, incrementing the counter value, and then storing the incremented counter value back to the memory. Other embodiments having various error statistics collecting and tracking functions performed in various combinations of hardware and software are contemplated.

In some embodiments, the Error Statistics Collecting/Tracking block is enabled to retain a history of information over time and to calculate a history-aware raw BER in view of the history. For example, the Error Statistics Collecting/Tracking block is enabled to retain a history of measured (or estimated) raw BER (such as per block or per page versus per access or per operational time) and to determine a history-aware measured (or estimated) raw BER from the history.

An error correcting code selected for encoding is determined dynamically, according to various criteria, usage scenarios, and embodiments. For example, a measured (or estimated) raw BER dynamically affects which error correcting code is selected for encoding. For another example, a history-aware measured (or estimated) raw BER affects which error correcting code is selected for encoding. An error correcting code selected for decoding of a particular portion of flash storage is determined dynamically to match the encoding used when last writing the particular portion.

Various embodiments perform selection of an error correcting code for encoding without explicit calculation of a raw BER (measured or estimated) but rather directly dynamically select the error correcting code based on one or more parameters or a history of one or more parameters. The parameters include number of errors corrected and/or detected, number of PE cycles, number of read cycles, a program time, an erase time, a read time, a temperature, and a threshold voltage. In various embodiments, the parameters (and/or the histories thereof) are per flash storage portion (such as per page or per block of the flash storage).

In some embodiments, a flash memory (such as included in the Flash unit) is organized in portions (such as pages or blocks) and each of the portions is enabled to store a pre-determined amount of information (such as 2K or 4K bytes of information). The information includes data information and error correcting information. In some embodiments, every portion is enabled to store a same particular number of bytes as error correcting information, and in other embodiments, some portions are enabled to store different numbers of bytes of error correcting information. Various error correcting codes (such as described by the Code Library) produce differing numbers of bytes (or bits) of error correcting information.

For example, encoding via a first error correcting code (such as used relatively early in a lifetime of a flash memory) produces relatively fewer bytes of error correcting information (e.g. redundant information for error correction) as compared to a second error correcting code (such as used later in the lifetime). In some embodiments, the flash memory (and/or use thereof) is enabled to store error correcting information sufficient for encoding via the second error correcting code within each portion, leaving error correcting information storage unused when the first error correcting code is used. In other embodiments, the flash memory (and/or use thereof) is enabled to store error correcting information sufficient for encoding via the first error correcting code within each portion and is unable to store (within each portion) error correcting information sufficient for encoding via the second error correcting code. Some of the other embodiments include additional flash memory storage (such as a region of the flash memory dedicated to storing additional error correcting information) that in combination with the per-portion error correcting information storage are sufficient to store error correcting information encoded via the second error correcting code.

In some embodiments, a flash memory is operated as portions (such as pages or blocks or multiples thereof), and each portion is organized as a data sub-portion and a respective corresponding error correcting sub-portion. The flash memory (and/or use thereof) is enabled to encode a particular quantum of storage data according to a dynamically selected particular one of a plurality of error correcting codes, producing error correcting information corresponding to the particular quantum of storage data. The storage data, in combination with the error correcting information, are stored in a combination of a particular one of the data sub-portions and the corresponding particular one of the error correcting sub-portions. The portions are all a same size, or alternately of differing sizes.

For example, the flash memory (and/or use thereof), is enabled to store error correcting information, large enough for encoding via a relatively smaller error correcting code, entirely in the error correcting sub-portion, leaving all of the corresponding data sub-portion available for storing storage data (that the error correcting information is produced from). However, the error correcting sub-portion is not large enough to store error correcting information encoded via a relatively larger error correcting code. Instead, an amount of the data storage sub-portion is ‘borrowed’ for storing a remainder of the error correcting information that docs not fit in the error correcting sub-portion, thus decreasing (by the amount borrowed) space available for storing storage data in the data storage sub-portion. Thus the quantum of storage data is less when using the relatively larger error correcting code, compared to the quantum of storage data when using the relatively smaller error correcting code, as relatively less of the data storage sub-portion is available. Therefore relatively less total usable space is provided by the flash memory (and/or use thereof) when using the relatively larger error correcting code.

For another example, the flash memory (and/or use thereof), is enabled to store error correcting information, large enough for encoding via a relatively larger error correcting code, entirely in the error correcting sub-portion, leaving all of the corresponding data sub-portion available for storing storage data (that the error correcting information is produced from). The error correcting sub-portion is more than large enough to store error correcting information encoded via a relatively smaller error correcting code. An amount of the error correcting sub-portion, up to and including all space remaining in the error correcting sub-portion after accounting for the error correcting information encoded via the relatively smaller error correcting code, is ‘borrowed’ for storing additional storage data. Thus the quantum of storage data is more when using the relatively smaller error correcting code, compared to the quantum of storage data when using the relatively larger error correcting code, as relatively more of the data storage sub-portion is available. Therefore relatively more total usable space is provided by the flash memory (and/or use thereof) when using the relatively smaller error correcting code.

In various embodiments and/or usage scenarios, some portions of a flash memory are operated according to the aforementioned borrowing from data sub-portions (e.g. as needed when encoding according to an error correcting code that “overflows” an error correcting sub-portion), while other portions of the flash memory are operated according to the aforementioned borrowing from error correcting sub-portions (e.g. as possible when encoding according to an error correcting code that leaves space available in a data sub-portion). In various embodiments and/or usage scenarios, some portions of a flash memory are operated by borrowing from either data or error correcting sub-portions (e.g. as needed depending on an error correcting code used for encoding). The portions are of a same size or of various sizes, and the portions are organized with a same allocation of data (or error correcting) sub-portions or of varying allocations (e.g. all data sub-portions are of a particular size, or all data sub-portions are any of a plurality of sizes).

In various embodiments, a usage mode of a portion of a flash memory is changed based on one or more of a raw BER and/or the aforementioned parameters that are used to dynamically select an error correcting code for encoding data information. For example, when a raw BER exceeds a threshold, a portion (such as a page) of flash memory previously operated as an MLC page is thereafter operated as an SLC page (such as by operating the page as a “lower only” page). For another example, during ah early part of a lifetime of a portion of a flash memory, the portion is operated as an MLC portion, and during a later part of the lifetime, the portion is operated as an SLC portion. Space available to store data is reduced when the portion is operated as an SLC portion (compared to an MLC portion), but the available space is more than if the portion were marked as unusable during the later part of the lifetime.

In various embodiments, dynamic selection of error correction code for encoding is used in conjunction with dynamic selection of flash portion operating mode. For example, during an initial operating period of a page of a flash memory, the page is operated as an MLC page and encoded with a first short code length ECC. During a subsequent operating period, the page is still operated as an MLC page, but is encoded according to a first long code length ECC. During a further subsequent operating period, the page is operated as an SLC page and encoded with a second short code length ECC. During a still further subsequent operating period, the page is still operated as an SLC page, but it is encoded according to a second long code length ECC. Space available to store data is reduced over the operating periods (as the page is encoded with the first short code length ECC, then with the first long code length ECC, then operated as an SLC page with the second short code length ECC, and then with the second long code length ECC), but the available space is more than if the page were marked as unusable.

Alternatively, while a raw BER of a page of a flash memory is less than a first threshold, the page is operated as an MLC page and encoded with a first short code length ECC. If/when the raw BER exceeds the first threshold (but remains less than a second threshold), then the page is encoded with a first longer code length ECC (while still operated as an MLC page). If/when the raw BER exceeds the second threshold (but remains less than a third threshold), then the page is encoded with an even longer code length ECC. If/when the raw BER exceeds the third threshold (but remains less than a fourth threshold), then the page is operated as an SLC page and encoded with a second short code length ECC. If/when the raw BER exceeds the fourth threshold, then the page continues to be operated as an SLC page and is encoded with a second longer code length ECC.

In some embodiments, a page is operated in a first operating mode (such as an MLC page) and an error correcting code used to encode data for the page is dynamically selected (such as according to any of the aforementioned parameters). If error correcting code information used in accordance with the dynamically selected error correcting code exceeds a threshold, then the page is operated in a second operating mode (such as an SLC page).

In various embodiments and/or usage scenarios, under particular circumstances a page is operated as an SLC page irrespective of error correcting code selection. Examples of the particular circumstances include the page being used for data that is accessible frequently, data that is written frequently, and/or data that benefits from a higher throughput.

In various embodiments and/or usage scenarios, portions (e.g. pages, blocks, or multiples thereof) of a flash memory are operated with shorter error correcting codes earlier in a lifetime of the flash memory, compared to longer error correcting codes later in the lifetime. Thus an increased effective amount of the flash memory is available for user data, and therefore longevity of the flash memory is increased by effective over provisioning. For example, a flash memory device has a page size slightly greater than a power of two, such as 8936 (744+2¹³) bytes. Varying a proportion of the page that is reserved for user data to be larger than the power or two early in the flash memory device lifetime, and to be Jess than the power of two later in the lifetime, extends the lifetime compared to using a same proportion throughout the lifetime.

### Ssd Controller Implementation

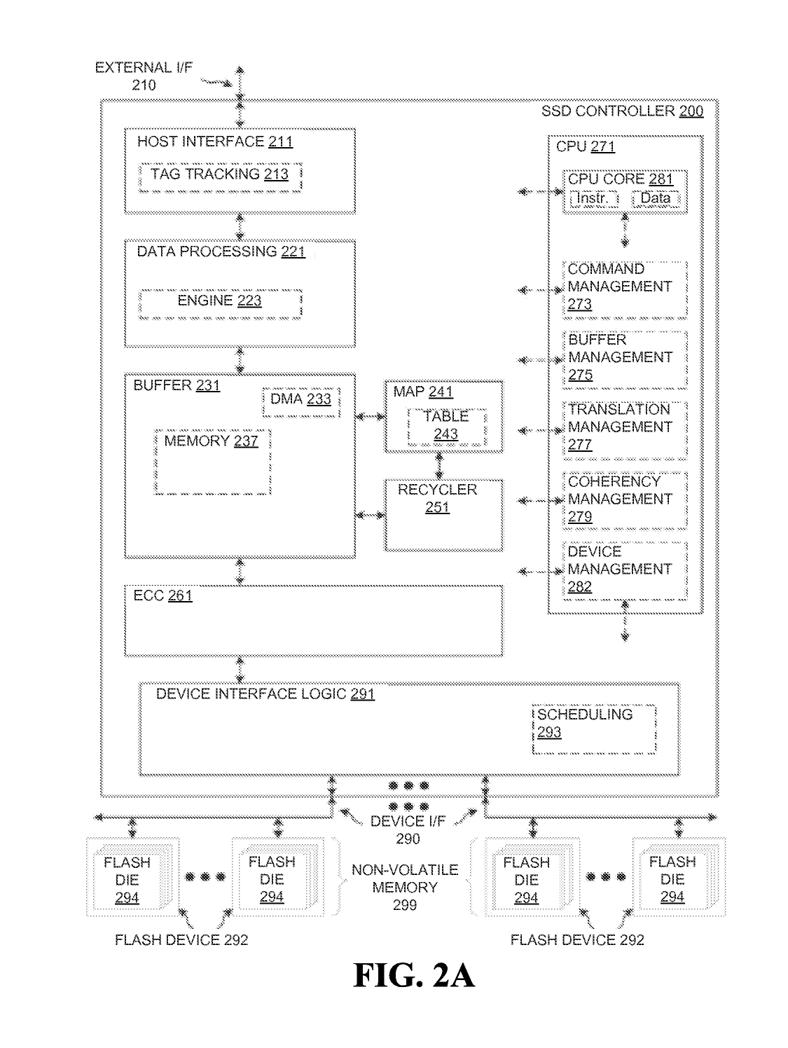

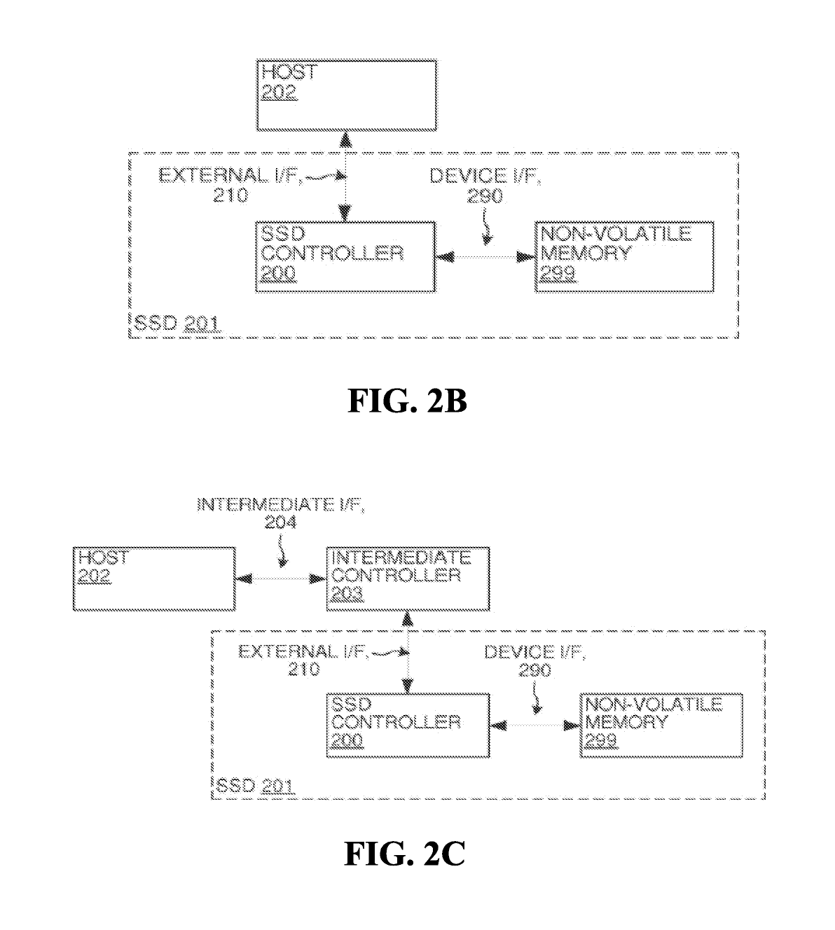

FIG. 2 A illustrates selected details of an embodiment of an SSD including an SSD controller using adaptive ECC techniques for flash memory biased data storage. SSD controller 200 is communicatively coupled via one or more external interfaces 210 to a host (not illustrated). According to various embodiments, external interfaces 210 are one or more of: a SATA interface; a SAS interface; a PCIe interface; a Fibre Channel interface; an Ethernet Interface (such as 10 Gigabit Ethernet); a non-standard version of any of the preceding interfaces; a custom interface; or any other type of interface used to interconnect storage and/or communications and/or computing devices. For example, in some embodiments, SSD controller 200 includes a SATA interface and a PCIe interface.

SSD controller 200 is further communicatively coupled via one or more device interfaces 290 to non-volatile memory 299 including one or more storage devices, such as flash devices 292. According to various embodiments, device interfaces 290 are one or more of: an asynchronous interface; a synchronous interface; a DDR synchronous interface; an ONFI compatible interface, such as an ONFI 2.2 compatible interface; a Toggle-mode compatible flash interface; a non-standard version of any of the preceding interfaces; a custom interface; or any other type of interface used to connect to storage devices.

Flash devices 292 have, in some embodiments, one or more individual flash die 294. According to type of a particular one of flash devices 292, a plurality of flash die 294 in the particular flash device 292 are optionally and/or selectively accessible in parallel. Flash devices 292 are merely representative of one type of storage device enabled to communicatively couple to SSD controller 200. In various embodiments, any type of storage device is usable, such as an SLC NAND flash memory, MLC NAND flash memory, NOR flash memory, read-only memory, static random access memory, dynamic random access memory, ferromagnetic memory, phase-change memory, racetrack memory, or any other type of memory device or storage medium.

According to various embodiments, device interfaces 290 are organized as: one or more busses with one or more flash devices 292 per bus; one or more groups of busses with one or more flash devices 292 per bus, where busses in a group are generally accessed in parallel; or any other organization of flash devices 292 onto device interfaces 290.

Continuing in FIG. 2A, SSD controller 200 has one or more modules, such as host interface 211, data processing 221, buffer 231, map 241, recycler 251, ECC 261, device interface logic 291, and CPU 271. The specific modules and interconnections illustrated in FIG. 2A are merely representative of one embodiment, and many arrangements and interconnections of some or all of the modules, as well as additional modules not illustrated, are conceived. In a first example, in some embodiments, there are two or more host interfaces 211 to provide dual-porting. In a second example, in some embodiments, data processing 221 and/or ECC 261 are combined with buffer 231. In a third example, in some embodiments, host interfaces 211 is directly coupled to buffer 231, and data processing 221 optionally and/or selectively operates on data stored in buffer 231. In a fourth example, in some embodiments, device interface logic 291 is directly coupled to buffer 231, and ECC 261 optionally and/or selectively operates on data stored in buffer 231.

Host interface 211 sends and receives commands and/or data via external interface 210, and, in some embodiments, tracks progress of individual commands via tag tracking 213. For example, the commands include a read command specifying an address (such as an LBA) and an amount of data (such as a number of LBA quanta, e.g. sectors) to read; in response the SSD provides read status and/or read data. For another example, the commands include a write command specifying an address (such as an LBA) and an amount of data (such as a number of LBA quanta, e.g. sectors) to write; in response the SSD provides write status and/or requests write data and optionally subsequently provides write status. For yet another example, the commands include a de-allocation command specifying an address (such as an LBA) that no longer need be allocated; in response the SSD modifies the map accordingly and optionally provides de-allocation status. For yet another example, the commands include a super capacitor test command or a data hardening success query; in response, the SSD provides appropriate status. In some embodiments, host interface 211 is compatible with the SATA protocol and, using NCQ commands, is enabled to have up to 32 pending commands, each with a unique tag represented as a number from 0 to 31. In some embodiments, tag tracking 213 is enabled to associate an external tag for a command received via external interface 210 with an internal tag used to track the command during processing by SSD controller 200.

According to various embodiments, one or more of: data processing 221 optionally and/or selectively processes some or all data sent between buffer 231 and external interfaces 210; and data processing 221 optionally and/or selectively processes data stored in buffer 231. In some embodiments, data processing 221 uses one or more engines 223 to perform one or more of: formatting; reformatting; transcoding; and any other data processing and/or manipulation task.

Buffer 231 stores data sent to/from external interfaces 210 from/to device interfaces 290. In some embodiments, buffer 231 additionally stores system data, such as some or all map tables, used by SSD controller 200 to manage flash devices 292. In various embodiments, buffer 231 has one or more of: memory 237 used for temporary storage of data; DMA 233 used to control movement of data to and/or from buffer 231; and other data movement and/or manipulation functions.

According to various embodiments, one or more of: ECC 261 optionally and/or selectively processes some or all data sent between buffer 231 and device interfaces 290; and ECC 261 optionally and/or selectively processes data stored in buffer 231.

Device interface logic 291 controls flash devices 292 via device interfaces 290. Device interface logic 291 is enabled to send data to/from flash devices 292 according to a protocol of flash devices 292. Device interface logic 291 includes scheduling 293 to selectively sequence control of flash devices 292 via device interfaces 290. For example, in some embodiments, scheduling 293 is enabled to queue operations to flash devices 292, and to selectively send the operations to individual ones of flash devices 292 (or flash die 294) as individual flash devices 292 (or flash die 294) are available.

Map 241 converts between data addressing used on external interfaces 210 and data addressing used on device interfaces 290, using table 243 to map external data addresses to locations in non-volatile memory 299. For example, in some embodiments, map 241 coverts LBAs used on external interfaces 210 to block and/or page addresses targeting one or more flash die 294, via mapping provided by table 243. For LBAs that have never been written since drive manufacture or de-allocation, the map points to a default value to return if the LBAs are read. For example, when processing a de-allocation command, the map is modified so that entries corresponding to the de-allocated LBAs point to one of the default values. In various embodiments, there are a plurality of default values, each having a corresponding pointer. The plurality of default values enables reading some de-allocated LBAs (such as in a first range) as one default value, while reading other dc-allocated LBAs (such as in a second range) as another default value. The default values, in various embodiments, are defined by flash memory, hardware, firmware, command/primitive arguments/parameters, programmable registers, or various combinations thereof.

In some embodiments, recycler 251 performs garbage collection. For example, in some embodiments, flash devices 292 contain blocks that must be erased before the blocks are re-writeable. Recycler 251 is enabled to determine which portions of flash devices 292 are actively in use (e.g. allocated instead of de-allocated), such as by scanning a map maintained by map 241, and to make unused (e.g. de-allocated) portions of flash devices 292 available for writing by erasing them. In further embodiments, recycler 251 is enabled to move data stored within flash devices 292 to make larger contiguous portions of flash devices 292 available for writing.

CPU 271 controls various portions of SSD controller 200. CPU 271 includes CPU core 281. CPU core 281 is, according to various embodiments, one or more single-core or multi-core processors. The individual processors cores in CPU core 281 are, in some embodiments, multi-threaded. CPU core 281 includes instruction and/or data caches and/or memories. For example, the instruction memory contains instructions to enable CPU core 281 to execute software (sometimes called firmware) to control SSD controller 200. In some embodiments, some or all of the firmware executed by CPU core 281 is stored on flash devices 292.

In various embodiments, CPU 271 further includes: command management 273 to track and control commands received via external interfaces 210 while the commands are in progress; buffer management 275 to control allocation and use of buffer 231; translation management 277 to control map 241; coherency management 279 to control consistency of data addressing and to avoid conflicts such as between external data accesses and recycle data accesses; device management 282 to control device interface logic 291; and optionally other management units. None, any, or all of the management functions performed by CPU 271 are, according to various embodiments, controlled and/or managed by hardware, by software (such as software executing on CPU core 281 or on a host connected via external interfaces 210), or any combination thereof.

In some embodiments, CPU 271 is enabled to perform other management tasks, such as one or more of: gathering and/or reporting performance statistics; implementing SMART; controlling power sequencing, controlling and/or monitoring and/or adjusting power consumption; responding to power failures; controlling and/or monitoring and/or adjusting clock rates; and other management tasks.

Various embodiments include a computing-host flash memory controller that is similar to SSD controller 200 and is compatible with operation with various computing hosts, such as via adaptation of host interface 211 and/or external interface 210. The various computing hosts include one or any combination of a computer, a workstation computer, a server computer, a storage server, a PC, a laptop computer, a notebook computer, a netbook computer, a PDA, a media player, a media recorder, a digital camera, a cellular handset, a cordless telephone handset, and an electronic game.

In various embodiments, all or any portions of an SSD controller (or a computing-host flash memory controller) are implemented on a single IC, a single die of a multi-die IC, a plurality of dice of a multi-die IC, or a plurality of ICs. For example, buffer 231 is implemented on a same die as other elements of SSD controller 200. For another example, buffer 231 is implemented on a different die than other elements of SSD controller 200.

In various embodiments, elements of SSD controller 200 implement various hardware blocks of FIG. 1 (or functions performed by the hardware blocks) in whole or in part. For example, ECC 261 implements one or more functions performed by the Error Statistics Collecting/Tracking, Universal Encoder, Universal Decoder, and/or Code Library hardware blocks of FIG. 1, For another example, device interface logic 291 implements one or more functions performed by the Control/Interface hardware block of FIG. 1, and non-volatile memory 299 implements the Flash unit of FIG. 1.

FIG. 2B illustrates selected details of another embodiment of a system including the SSD of FIG. 2A. SSD 201 includes SSD controller 200 coupled to non-volatile memory 299 via device interfaces 290. The SSD is coupled to host 202 via external interfaces 210. In some embodiments, SSD 201 (or variations thereof) corresponds to a SAS drive or a SATA drive that is coupled to an initiator operating as host 202.

FIG. 2C illustrates selected details of another embodiment of a system including the SSD of FIG. 2A. As in FIG. 2B, SSD 201 includes SSD controller 200 coupled to non-volatile memory 299 via device interfaces 290. The SSD is coupled to host 202 via external interfaces 210 in turn coupled to intermediate controller 203 and then to host 202 via intermediate interfaces 204. In various embodiments, SSD controller 200 is coupled to the host via one or more intermediate levels of other controllers, such as a RAID controller. In some embodiments, SSD 201 (or variations thereof) corresponds to a SAS drive or a SATA drive and intermediate controller 203 corresponds to an expander that is in turn coupled an initiator, or alternatively intermediate controller 203 corresponds to a bridge that is indirectly coupled to an initiator via an expander.

In various embodiments, an SSD controller and/or a computing-host flash memory controller in combination with one or more non-volatile memories are implemented as a non-volatile storage component, such as a USB storage component, a CF storage component, an MMC storage component, an SD storage component, a Memory Stick storage component, and an xD-picture card storage component.

In various embodiments, all or any portions of an SSD controller (or a computing-host flash memory controller), or functions thereof, are implemented in a host that the controller is to be coupled with (e.g. host 202 of FIG. 2C). In various embodiments, all or any portions of an SSD controller (or a computing-host flash memory controller), or functions thereof, are implemented via hardware (e.g. logic circuitry), software (e.g. driver program), or any combination thereof. For example, functionality of or associated with an ECC unit (such as similar to ECC 261 of FIG. 2A) is implemented partially via software on a host and partially via hardware in an SSD controller. For another example, functionality of or associated with a recycler unit (such as similar to recycler 251 of FIG. 2A) is implemented partially via software on a host and partially via hardware in a computing-host flash memory controller.

### Example Implementation Techniques

In some embodiments, various combinations of all or portions of operations performed by a system implementing adaptive ECC techniques for flash memory based data storage, e.g. the hardware blocks of FIG. 1, a computing-host flash memory controller, and/or an SSD controller (such as SSD controller 200 of FIG. 2A), and portions of a processor, microprocessor, system-on-a-chip, application-specific-integrated-circuit, hardware accelerator, or other circuitry providing all or portions of the aforementioned operations, are specified by a specification compatible with processing by a computer system. The specification is in accordance with various descriptions, such as hardware description languages, circuit descriptions, netlist descriptions, mask descriptions, or layout descriptions. Example descriptions include: Verilog, VHDL, SPICE, SPICE variants such as Pspice, IBIS, LEF, DEF, GDS-II, OASIS, or other descriptions. In various embodiments, the processing includes any combination of interpretation, compilation, simulation, and synthesis to produce, to verify, or to specify logic and/or circuitry suitable for inclusion on one or more integrated circuits. Each integrated circuit, according to various embodiments, is designable and/or manufacturable according to a variety of techniques. The techniques include a programmable technique (such as a field or mask programmable gate array integrated circuit), a semi-custom technique (such as a wholly or partially cell-based integrated circuit), and a full-custom technique (such as an integrated circuit that is substantially specialized), any combination thereof, or any other technique compatible with design and/or manufacturing of integrated circuits.

In some embodiments, various combinations of all or portions of operations as described by a computer readable medium having a set of instructions stored therein, are performed by execution and/or interpretation of one or more program instructions, by interpretation and/or compiling of one or more source and/or script language statements, or by execution of binary instructions produced by compiling, translating, and/or interpreting information expressed in programming and/or scripting language statements. The statements are compatible with any standard programming or scripting language (such as C, C++, Fortran, Pascal, Ada, Java, VBscript, and Shell). One or more of the program instructions, the language statements, or the binary instructions, are optionally stored on one or more computer readable storage medium elements. In various embodiments some, all, or various portions of the program instructions are realized as one or more functions, routines, sub-routines, in-line routines, procedures, macros, or portions thereof.

### CONCLUSION

Certain choices have been made in the description merely for convenience in preparing the text and drawings and unless there is an indication to the contrary the choices should not be construed per se as conveying additional information regarding structure or operation of the embodiments described. Examples of the choices include: the particular organization or assignment of the designations used for the figure numbering and the particular organization or assignment of the clement identifiers (the callouts or numerical designators, e.g.) used to identify and reference the features and elements of the embodiments.

The words “includes” or “including” are specifically intended to be construed as abstractions describing logical sets of open-ended scope and are not meant to convey physical containment unless explicitly followed by the word “within.”

Although the foregoing embodiments have been described in some detail for purposes of clarity of description and understanding, the invention is not limited to the details provided. There are many embodiments of the invention. The disclosed embodiments are exemplary and not restrictive.

It will be understood that many variations in construction, arrangement, and use are possible consistent with the description, and are within the scope of the claims of the issued patent. For example, interconnect and function-unit bit-widths, clock speeds, and the type of technology used are variable according to various embodiments in each component block. The names given to interconnect and logic are merely exemplary, and should not be construed as limiting the concepts described. The order and arrangement of flowchart and flow diagram process, action, and function elements are variable according to various embodiments. Also, unless specifically stated to the contrary, value ranges specified, maximum and minimum values used, or other particular specifications (such as flash memory technology types; and the number of entries or stages in registers and buffers), are merely those of the described embodiments, are expected to track improvements and changes in implementation technology, and should not be construed as limitations.

Functionally equivalent techniques known in the art are employable instead of those described to implement various components, sub-systems, operations, functions, routines, sub-routines, in-line routines, procedures, macros, or portions thereof. It is also understood that many functional aspects of embodiments are realizable selectively in either hardware (i.e., generally dedicated circuitry) or software (i.e., via some manner of programmed controller or processor), as a function of embodiment dependent design constraints and technology treads of faster processing (facilitating migration of functions previously in hardware into software) and higher integration density (facilitating migration of functions previously in software into hardwire). Specific variations in various embodiments include, but are not limited to: differences in partitioning; different form factors and configurations; use of different operating systems and other system software; use of different interface standards, network protocols, or communication links; and other variations to be expected when implementing the concepts deserved herein in accordance with the unique engineering and business constraints of a particular application.

The embodiments have been described with detail and environmental context well beyond that required for a minimal implementation of many aspects of the embodiments described. Those of ordinary skill in the art will recognize what some embodiments omit disclosed components or features without altering the basic cooperation among the remaining elements. It is thus understood that much of the details disclosed are not required to implement various aspects of the embodiments described. To the extent that the remaining elements are distinguishable from the prior art, components and features that are omitted are not limiting on the concepts described herein.

All such variations in design are insubstantial changes over the teachings conveyed by the described embodiments. It is also understood that the embodiments described herein have broad applicability to other computing and networking applications, and are not limited to the particular application or industry of the described embodiments. The invention is thus to be construed as including ail possible modifications and variations encompassed within the scope of the claims of the issued patent.

What is claimed is:

1. An apparatus comprising:
a controller configured to:
dynamically select an error correction code for encoding data for a specific portion of flash memory;
dynamically select an operating mode for the specific portion of the flash memory; and
store data to the specific portion of the flash memory based on a selected error correction code and a selected operating mode.

2. The apparatus of claim 1 further comprising dynamically selecting an error correction code for encoding data for the specific portion of flash memory includes selecting a first error correction code during a first period of operation of the flash memory, and, during a second period of operation of the flash memory, selecting a second error correction code, where the first error correction code and the second error correction code are different, and the second period is subsequent to the first period.

3. The apparatus of claim 2 further comprising a length of the first error correction code is shorter than a length of the second error correction code.

4. The apparatus of claim 2 further comprising dynamically select an operating mode for the specific portion of the flash memory includes implementing a first operating mode for the specific portion during the first period and implementing the first operating mode during the second period.

5. The apparatus of claim 4 further comprising the first operating mode is a multi-level cell operating mode where a multi-level cell is enabled to store multiple bits of information.

6. The apparatus of claim 4 further comprising dynamically select an operating mode for the specific portion of the flash memory includes implementing a second operating mode during a third period of operation of the flash memory, the third period subsequent to the second period.

7. The apparatus of claim 6 further comprising dynamically selecting an error correction code for encoding data for the specific portion of flash memory includes selecting a third error correction code during the third period of operation of the flash memory, the third error correction code different than the second error correction code and different than the first error correction code.

8. The apparatus of claim 7 further comprising a length of the third error correction code is shorter than a length of the second error correction code.

9. The apparatus of claim 7 further comprising dynamically selecting an error correction code for encoding data for the specific portion of flash memory includes selecting a fourth error correction code during a fourth period of operation of the flash memory, the fourth error correction code different than third error correction code, the second error correction code, and the first error correction code, the fourth period subsequent to the third period.

10. The apparatus of claim 9 further comprising dynamically select an operating mode for the specific portion of the flash memory includes implementing the second operating mode during the fourth period of operation of the flash memory.

11. The apparatus of claim 10 further comprising the second mode is a single-level cell operating mode where a single-level cell is enabled to store one bit of information.

12. The apparatus of claim 10 further comprising the controller configured to determine a bit error rate of the specific portion and dynamically select an error correction code for encoding data for the specific portion based on the bit error rate.

13. A device comprising:
circuitry configured to:
dynamically select an error correction code for encoding data for a specific portion of flash memory;
dynamically select an operating mode for the specific portion of the flash memory; and
store data to the specific portion of the flash memory based on a selected error correction code and a selected operating mode. 14. The device of claim 13 further comprising:
the circuitry configured to:
determine a bit error rate of the specific portion;
operate the specific portion in a multi-level cell operating mode with a first error correction code when the bit error rate is less than a first threshold;
operate the specific portion in the multi-level cell operating mode with a second error correction code when the bit error rate is greater than the first threshold but less than a second threshold;
operate the specific portion in a single-level cell operating mode with a third error correction code when the bit error rate is greater than the second threshold but less than a third threshold; and
operate the specific portion in the single-level cell operating mode with a fourth error correction code when the bit error rate is greater than the third threshold.

15. The device of claim 14 further comprising the first error correction code has a shorter length than the second error correction code and the third error correction code has a shorter length than fourth error correction code.

16. The device of claim 13 further comprising:
the circuitry configured to:
during a first period of operation of the flash memory,
implement a first error correction code and a first operating mode for the specific portion;
during a second period of operation of the flash memory, the second period subsequent to the first period,
implement a second error correction code and the first operating mode for the specific portion;
during a third period of operation of the flash memory, the third period subsequent to the second period,
implement a third error correction code and a second operating mode for the specific portion; and
during a fourth period of operation of the flash memory, the fourth period subsequent to the third period,
implement a fourth error correction code and the second operating mode for the specific portion.

17. A memory device storing instructions that when executed by a processor cause the processor to perform a process comprising:
dynamically selecting an error correction code for encoding data for a specific portion of flash memory;
dynamically selecting an operating mode for the specific portion of the flash memory; and
storing data to the specific portion of the flash memory based on a selected error correction code and a selected operating mode.

18. The memory device of claim 17, the process further comprising:
determining a bit error rate of the specific portion;
operating the specific portion in a multi-level cell operating mode with a first error correction code when the bit error rate is less than a first threshold;
operating the specific portion in the multi-level cell operating mode with a second error correction code when the bit error rate is greater than the first threshold but less than a second threshold;
operating the specific portion in a single-level cell operating mode with a third error correction code when the bit error rate is greater than the second threshold but less than a third threshold; and
operating the specific portion in the single-level cell operating mode with a fourth error correction code when the bit error rate is greater than the third threshold. 19. The memory device of claim 17, the process further comprising:
during a first period of operation of the flash memory, implementing a first error correction code and a first operating mode for the specific portion;
during a second period of operation of the flash memory, the second period subsequent to the first period, implementing a second error correction code and the first operating mode for the specific portion;
during a third period of operation of the flash memory, the third period subsequent to the second period, implementing a third error correction code and a second operating mode for the specific portion; and
during a fourth period of operation of the flash memory, the fourth period subsequent to the third period, implementing a fourth error correction code and the second operating mode for the specific portion.

20. The memory device of claim 19, further comprising the first operating mode is a multi-level bit cell mode, the second operating mode is a single-level bit cell mode, the first error correction code has a length shorter than the second error correction code, and the third error correction code has a length shorter than the fourth error correction code.
